(19) United States
(12) Patent Application Publication
(10) Pub. No.: US 2022/0020589 A1
(43) Pub. Date: Jan. 20, 2022

(54) DIELECTRIC COATING FOR DEPOSITION CHAMBER

(71) Applicant: Applied Materials, Inc., Santa Clara, CA (US)

(72) Inventors: Lu Xu, San Jose, CA (US); Ratsamee Limdulpaiboon, San Jose, CA (US); Kwangduk Douglas Lee, Redwood City, CA (US)

(73) Assignee: Applied Materials, Inc., Santa Clara, CA (US)

(21) Appl. No.: 16/932,791

(22) Filed: Jul. 19, 2020

(51) Int. Cl. H01L 21/033; C23C 16/40; C23C 16/505; C23C 16/04

(52) U.S. Cl. CPC H01L 21/0332; C23C 16/042; C23C 16/505; C23C 16/401

(57) ABSTRACT

Exemplary methods of semiconductor processing may include forming a first plasma of a silicon-containing precursor and an oxygen-containing precursor within a processing region of a semiconductor processing chamber. The methods may also include depositing a coating from first effluents of the first plasma on surfaces defining the processing region to a target thickness greater than or about 0.5 μm. Forming the first plasma may occur at a first power greater than or about 300 W. The surfaces defining the processing region may include a surface of a faceplate that faces the processing region.

### TECHNICAL FIELD

The present technology relates to methods and components for semiconductor processing. More specifically, the present technology relates to systems and methods for preparing chambers for semiconductor processing.

### BACKGROUND

Integrated circuits are made possible by processes that produce intricately patterned material layers on substrate surfaces. Producing patterned material on a substrate requires controlled methods for forming and removing material. As throughput continues to increase, particle contamination may be an increasing challenge. During plasma-enhanced deposition, in situ plasma formation may expose chamber surfaces to radical species. The exposure may damage these surfaces, which may cause contaminating material to fall onto the substrate during deposition. This may adversely affect device quality.

Thus, there is a need for improved systems and methods that can be used to produce high quality devices and structures. These and other needs are addressed by the present technology.

### SUMMARY

Exemplary methods of semiconductor processing may include forming a first plasma of a silicon-containing precursor and an oxygen-containing precursor within a processing region of a semiconductor processing chamber. The methods may also include depositing a coating from first effluents of the first plasma on surfaces defining the processing region to a target thickness of greater than or about 0.5 μm. Forming the first plasma may occur at a first power of greater than or about 300 W. The surfaces defining the processing region may include a surface of a faceplate that faces the processing region.

In some embodiments, a flow rate of the silicon-containing precursor may be maintained at less than or about 200 sccm. The silicon-containing precursor may include silane. The coating may include silicon oxide.

The surfaces defining the processing region may also include a surface of a substrate support. A temperature of the processing region may be maintained at greater than or about 600° C. during the depositing of the coating. The first power may be approximately 500 W. The first plasma may be formed by a high-frequency radio frequency (HFRF) process.

The methods may also include, after depositing the coating, forming a second plasma within the processing region, and depositing a hardmask film from second effluents of the second plasma on a substrate within the processing region. Forming the second plasma may occur at a second plasma power greater than or about 2500 W. The hardmask film may include amorphous carbon. The second power may be approximately 2950 W.

The methods may also include, after depositing the hardmask film, removing the coating from the surfaces defining the processing region. The removing may be performed with a plasma. The plasma for removing may be formed at a power of greater than or about 2000 W. The plasma for removing may be formed at a power of less than or about 2800 W.

Some embodiments of the present technology may encompass methods of forming a first plasma of a silicon-containing precursor and an oxygen-containing precursor within a processing region of a semiconductor processing chamber. The methods may include depositing a coating from first effluents of the first plasma on surfaces defining the processing region, subsequently forming a second plasma within the processing region, and depositing a hardmask film from second effluents of the second plasma on a substrate within the processing region. The coating may be characterized by a density greater than or about 2.8 g/cm³. Forming the first plasma may occur at a first power greater than or about 300 W, and forming the second plasma may occur at a second power greater than or about 2500 W. The coating may be formed to have a refractive index greater than 1.46.

The methods may also include forming a plasma of a halogen-containing precursor, and removing the coating from surfaces defining the processing region. The plasma of the halogen-containing precursor may be formed at a plasma power of greater than or about 2000 W.

Some embodiments of the present technology may encompass methods of forming a first plasma of a silicon-containing precursor and an oxygen-containing precursor within a processing region of a semiconductor processing chamber, depositing a coating from first effluents of the first plasma on surfaces defining the processing region, subsequently forming a second plasma within the processing region, and depositing a hardmask film from second effluents of the second plasma on a substrate within the processing region. The coating may be characterized by an internal stress of less than −175 MPa. Forming the first plasma may occur at a first power greater than or about 300 W, and forming the second plasma may occur at a second power greater than or about 2500 W.

The methods may also include forming a plasma of a halogen-containing precursor, and removing the coating from surfaces defining the processing region. The plasma of the halogen-containing precursor may be formed at a plasma power of greater than or about 2000 W.

Such technology may provide numerous benefits over conventional systems and techniques. For example, embodiments of the present technology may enable increased deposition rate and the clean rate by allowing for increased power during these processes. By depositing a protective coating on the faceplate of the chamber, the methods may limit or minimize deposition of falling particles onto substrates during subsequent deposition processes. Further, by depositing the protective coating on the substrate support, the methods may reduce the rate at which the substrate support needs to be replaced due to damage from ion bombardment. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary plasma system according to some embodiments of the present technology.

FIG. 2 shows operations in a semiconductor processing method according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Hardmask films are utilized for a number of processing operations, which may include forming patterns through multiple layers of different materials. Increasing throughput when forming hardmask films may reduce costs and increase efficiency. One way to improve throughput is to increase the power during deposition of the hardmask film and/or during cleaning of the chamber after deposition. The increased plasma power may increase plasma density and constituent plasma species for formation. However, when plasma power is increased over 2000 W, stronger ion bombardment may cause damage to surfaces within the processing chamber, such as the faceplate and/or the substrate support.

If the surface of the faceplate is damaged, material from the faceplate may fall onto the substrate during processing. This may cause arcing during processing and/or defects in the film, which increase a likelihood of device failure. For example, if the faceplate is made of aluminum, a carbon hardmask film may be contaminated by a significant number of aluminum particles. Further, if the surface of the substrate support is damaged, it may be necessary to replace the substrate support more frequently. In particular, protrusions from the surface of the substrate support may be eroded, which can detrimentally affect chucking efficiency and backside damage.

The present technology overcomes these issues by forming a protective coating on surfaces of the processing chamber before depositing the hardmask film. The coating may be formed by plasma deposition, and may include a dielectric material such as silicon oxides. While conventional seasoning may be formed to limit fall-on particles of deposition products at lower plasma power, conventional seasonings are typically easily removed, and deposition methods performed at increased plasma power may pit or remove conventional seasonings, which may actually increase fall-on particles on the substrate being processed. Coatings according to embodiments of the present technology may be formed to have a high density, a compressive stress, and/or a high adhesion to reduce ion impact on the film formed. These properties may be achieved by increasing the deposition power as compared with conventional methods. For example, the deposition power may be greater than or about 300 W, as compared with conventional deposition power of 200 W or less, which is often used to produce films that are more readily removed after processing. Accordingly, the coating may be more resistant to ion bombardment damage than conventional coatings. Further, the deposition power may be less than or about 600 W, because the deposition rate may decrease above 600 W, which would result in a decrease in throughput.

For example, the coating may limit or minimize deposition of falling particles onto substrates during subsequent deposition processes. Further, the coating may reduce or prevent erosion of the substrate support. In addition, the coating may minimize profile drift that can be caused by changes in the emissivity of the faceplate over time. These effects may allow a higher power to be used during deposition of the hardmask film, thereby improving throughput.

Although the remaining disclosure will routinely identify specific deposition processes utilizing the disclosed technology, it will be readily understood that the systems and methods are equally applicable to other deposition, etch, and cleaning chambers, as well as processes as may occur in the described chambers. Accordingly, the technology should not be considered to be so limited as for use with these specific deposition processes or chambers alone. The disclosure will discuss one possible chamber that may be used to perform processes according to embodiments of the present technology before additional variations and adjustments to this system according to embodiments of the present technology are described.

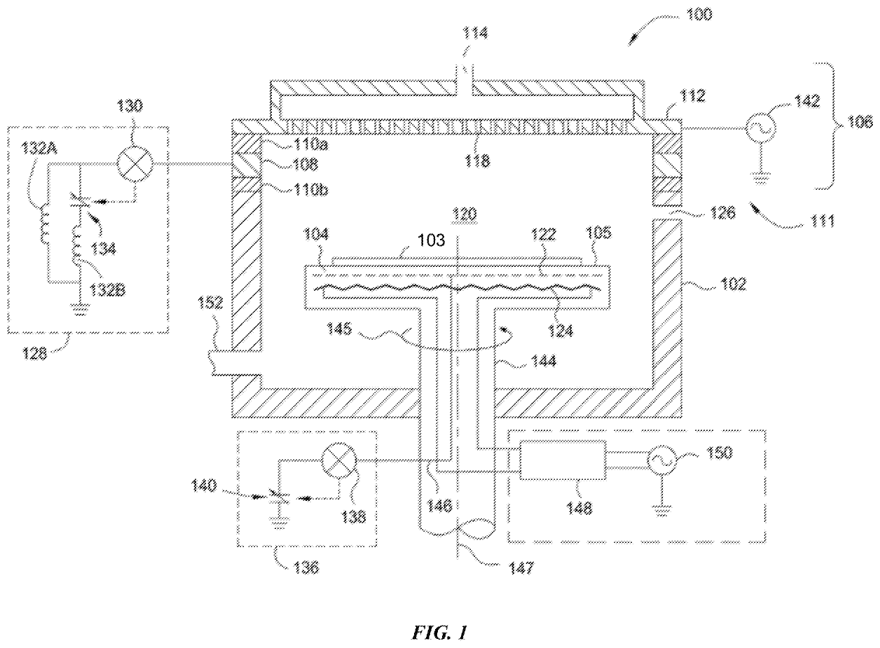

FIG. 1 shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers according to some embodiments of the present technology, although it is to be understood that the methods may similarly be performed in any chamber within which film formation may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. The substrate support 104 may be rotatable, as indicated by the arrow 145, along an axis 147, where a shaft 144 of the substrate support 104 may be located. Alternatively, the substrate support 104 may be lifted up to rotate as necessary during a deposition process. A plurality of protrusions may extend from the top surface of the substrate support 104, and may define a contact area for the substrate 103. Greater than or about 500 protrusions may be provided, and each protrusion may be characterized by a diameter of greater than or about 2 mm. Each protrusion may be characterized by a rounded corner profile having a corner radius of at least 10% of a height of the protrusion.

A plasma profile modulator 111 may be disposed in the processing chamber 100 to control plasma distribution across the substrate 103 disposed on the substrate support 104. The plasma profile modulator 111 may include a first electrode 108 that may be disposed adjacent to the chamber body 102, and may separate the chamber body 102 from other components of the lid assembly 106. The first electrode 108 may be part of the lid assembly 106, or may be a separate sidewall electrode. The first electrode 108 may be an annular or ring-like member, and may be a ring electrode. The first electrode 108 may be a continuous loop around a circumference of the processing chamber 100 surrounding the processing volume 120, or may be discontinuous at selected locations if desired. The first electrode 108 may also be a perforated electrode, such as a perforated ring or a mesh electrode, or may be a plate electrode, such as, for example, a secondary gas distributor.

One or more isolators 110a, 110b, which may be a dielectric material such as a ceramic or metal oxide, for example aluminum oxide and/or aluminum nitride, may contact the first electrode 108 and separate the first electrode 108 electrically and thermally from a gas distributor 112 and from the chamber body 102. The gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

The first electrode 108 may be coupled with a first tuning circuit 128 that may control a ground pathway of the processing chamber 100. The first tuning circuit 128 may include a first electronic sensor 130 and a first electronic controller 134. The first electronic controller 134 may be or include a variable capacitor or other circuit elements. The first tuning circuit 128 may be or include one or more inductors 132. The first tuning circuit 128 may be any circuit that enables variable or controllable impedance under the plasma conditions present in the processing volume 120 during processing. In some embodiments as illustrated, the first tuning circuit 128 may include a first circuit leg and a second circuit leg coupled in parallel between ground and the first electronic sensor 130. The first circuit leg may include a first inductor 132A. The second circuit leg may include a second inductor 132B coupled in series with the first electronic controller 134. The second inductor 132B may be disposed between the first electronic controller 134 and a node connecting both the first and second circuit legs to the first electronic sensor 130. The first electronic sensor 130 may be a voltage or current sensor and may be coupled with the first electronic controller 134, which may afford a degree of closed-loop control of plasma conditions inside the processing volume 120.

A second electrode 122 may be coupled with the substrate support 104. The second electrode 122 may be embedded within the substrate support 104 or coupled with a surface of the substrate support 104. The second electrode 122 may be a plate, a perforated plate, a mesh, a wire screen, or any other distributed arrangement of conductive elements. The second electrode 122 may be a tuning electrode, and may be coupled with a second tuning circuit 136 by a conduit 146, for example a cable having a selected resistance, such as 50 ohms, for example, disposed in the shaft 144 of the substrate support 104. The second tuning circuit 136 may have a second electronic sensor 138 and a second electronic controller 140, which may be a second variable capacitor. The second electronic sensor 138 may be a voltage or current sensor, and may be coupled with the second electronic controller 140 to provide further control over plasma conditions in the processing volume 120.

A third electrode 124, which may be a bias electrode and/or an electrostatic chucking electrode, may be coupled with the substrate support 104. The third electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power.

The lid assembly 106 and substrate support 104 of FIG. 1 may be used with any processing chamber for plasma or thermal processing. In operation, the processing chamber 100 may afford real-time control of plasma conditions in the processing volume 120. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the third electrode 124 in some embodiments.

Upon energizing a plasma in the processing volume 120, a potential difference may be established between the plasma and the first electrode 108. A potential difference may also be established between the plasma and the second electrode 122. The electronic controllers 134, 140 may then be used to adjust the flow properties of the ground paths represented by the two tuning circuits 128 and 136. A set point may be delivered to the first tuning circuit 128 and the second tuning circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Each of the tuning circuits 128, 136 may have a variable impedance that may be adjusted using the respective electronic controllers 134, 140. Where the electronic controllers 134, 140 are variable capacitors, the capacitance range of each of the variable capacitors, and the inductances of the first inductor 132A and the second inductor 132B, may be chosen to provide an impedance range. This range may depend on the frequency and voltage characteristics of the plasma, which may have a minimum in the capacitance range of each variable capacitor. Hence, when the capacitance of the first electronic controller 134 is at a minimum or maximum, impedance of the first tuning circuit 128 may be high, resulting in a plasma shape that has a minimum aerial or lateral coverage over the substrate support. When the capacitance of the first electronic controller 134 approaches a value that minimizes the impedance of the first tuning circuit 128, the aerial coverage of the plasma may grow to a maximum, effectively covering the entire working area of the substrate support 104. As the capacitance of the first electronic controller 134 deviates from the minimum impedance setting, the plasma shape may shrink from the chamber walls and aerial coverage of the substrate support may decline. The second electronic controller 140 may have a similar effect, increasing and decreasing aerial coverage of the plasma over the substrate support as the capacitance of the second electronic controller 140 may be changed.

The electronic sensors 130, 138 may be used to tune the respective circuits 128, 136 in a closed loop. A set point for current or voltage, depending on the type of sensor used, may be installed in each sensor, and the sensor may be provided with control software that determines an adjustment to each respective electronic controller 134, 140 to minimize deviation from the set point. Consequently, a plasma shape may be selected and dynamically controlled during processing. It is to be understood that, while the foregoing discussion is based on electronic controllers 134, 140, which may be variable capacitors, any electronic component with adjustable characteristic may be used to provide tuning circuits 128 and 136 with adjustable impedance.

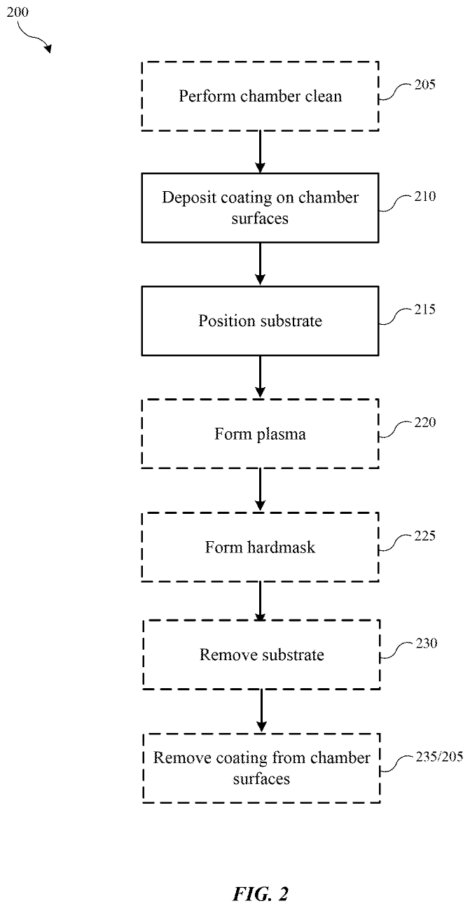

FIG. 2 shows exemplary operations in a processing method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the method, but are not critical to the technology, or may be performed by alternative methodology as would be readily appreciated.

Method 200 may include a processing method that may include a number of operations for preparing a chamber for processing a substrate, such as forming a hardmask film or other deposition operations. The method may include optional operations prior to initiation of method 200, or the method may include additional operations. For example, method 200 may include operations performed in different orders than illustrated. As will be explained, a number of repetitions may be performed, which may allow processing of subsequent substrates. For example, the method may be performed subsequent to processing of a previous substrate, which may end with a previous chamber clean in some embodiments at optional operation 205. Exemplary cleaning operations may utilize plasma enhanced halogen-containing or other etchant precursors, which may be used to remove deposition byproducts or previous chambers seasonings.

A seasoning or treatment coating may then be developed within the chamber at operation 210. For example, a dielectric material, such as silicon oxide, may be formed over exposed surfaces of the processing chamber, such as surfaces defining the processing region, of which processing volume 120 is an example. The processing region may be an internal plasma region, which may be at least partially defined by a number of chamber components. For example, chamber sidewalls, a showerhead or faceplate, and a substrate support may all be included in or at least partially define aspects of the processing region. A plasma may be formed within the processing region and precursors for depositing silicon oxide may be introduced. The plasma may include a silicon-containing precursor, such as silanes of any order including silane, or other silicon-containing materials, and an oxygen-containing precursor, such as oxygen, ozone, nitrous oxide, or other oxygen-containing materials. Including nitrogen in the oxygen-containing precursor may increase the density of the film. In some embodiments, the plasma may be formed between the substrate support 104 and the gas distributor 112, which is an example of a faceplate. A coating of silicon oxide may be formed from effluents of the plasma on the surfaces defining the processing region to a target thickness over the exposed surfaces.

In some embodiments, the target thickness may be greater than or about 0.5 μm, which may ensure sufficient coverage to protect the underlying components from plasma effluents during processing. When higher power plasma is utilized during deposition operations, increased bombardment may occur on the chamber coating. Accordingly, by forming a coating thickness of at least about 0.5 μm, access to the underlying chamber components may be minimized during processing under higher plasma power. Hence, in some embodiments the coating thickness may be greater than or about 0.8 μm, greater than or about 1.0 μm, greater than or about 1.2 μm, greater than or about 1.4 μm, greater than or about 1.6 μm, greater than or about 1.8 μm, greater than or about 2.0 μm, or greater. However, when coating thickness exceed a few micrometers, increased removal time may be needed, without necessarily increasing underlying component protection. Additionally, the increased dielectric may impact other operational parameters. For example, a thicker coating on a substrate support may impact substrate heating during processing, and may lower a processing temperature, which can impact properties of the film deposited. Accordingly, in some embodiments the chamber coatings may be maintained at less than or about 5.0 μm, and may be maintained at less than or about 4.0 μm, less than or about 3.0 μm, less than or about 2.5 μm, less than or about 2.0 μm, or less.

The coating may be formed by using a high-frequency radio frequency (HFRF) process. In some embodiments, the frequency may be greater than or about 13 MHz, greater than or about 27 MHz, greater than or about 40 MHz, or greater than or about 60 MHz. In general, a higher frequency may have a higher energy, and may be used to successfully ignite the plasma and react with the gas precursors.

Various deposition parameters may impact the material properties of the coating formed, and may be used to enhance the properties to ensure chamber surface protection during high-powered plasma operations. Some embodiments may form the chamber coating using a higher power than may be used conventionally. For example, while many conventional processes may utilize a plasma power below or about 200 W, which may produce coatings facilitating removal of the coating subsequent to processing, these films may be incapable of maintaining efficacy during higher power processing, and may be stripped during high power processing. The present technology may form chamber coatings with an HFRF power of greater than or about 300 W, and may utilize a plasma power of greater than or about 350 W, greater than or about 400 W, greater than or about 450 W, greater than or about 500 W, greater than or about 550 W, greater than or about 600 W, or higher. However, when plasma power continues to increase above 600 W, the RF plasma may attack more severely on the chamber coating while depositing at the same time, thereby reducing the deposition rate. The higher power may increase the density of the coating and may increase a compressive stress of the coating.

Further, the deposition may be performed at a higher temperature, such as greater than or about 400° C., and may be performed at a deposition temperature of greater than or about 450° C., greater than or about 500° C., greater than or about 550° C., greater than or about 600 ° C., greater than or about 650° C., greater than or about 700° C., or higher. A higher deposition temperature may increase cross-linking of the film, as well as removal of hydrogen and other species that may be incorporated within the lattice, which may further increase density and other material properties of the coating. Additionally, during deposition, a flow rate of the silicon-containing precursor may be maintained at greater than or about 50 sccm, and may be maintained at greater than or about 60 sccm, greater than or about 70 sccm, greater than or about 80 sccm, greater than or about 90 sccm, greater than or about 100 sccm, greater than or about 110 sccm, or higher. Maintaining a flow rate above a threshold flow rate may ensure sufficient deposition. However, as a flow rate of the silicon-containing precursor is further increased, the stress component of the film may shift to a more tensile nature, which may impact the material and the ability for the film to withstand higher powered ion bombardment. Accordingly, in some embodiments the flow rate of the silicon-containing precursor may be maintained below or about 200 sccm, and may be maintained below or about 180 sccm, below or about 160 sccm, below or about 140 sccm, below or about 120 sccm, or less.

The utilization of the parameters discussed above may produce a coating with a higher density capable of withstanding high-powered deposition processes. For example, the coating may be characterized by a density greater than or about 2.8 g/cm³, greater than or about 2.9 g/cm³, greater than or about 3.0 g/cm³, greater than or about 3.1 g/cm³, or about 3.2 g/cm³. In some examples, the density may be determined by the ratio of nitrogen to oxygen in the coating, such that the density may be adjusted by varying the ratio of nitrogen to oxygen in the precursors. In contrast, a conventional coating may be limited to densities below 2.8 g/cm³, or 2.6 g/cm³, based on the process issues as previously described. Further, the produced films may be characterized by a more compressive stress than a conventional coating, which may improve adherence on chamber components during processing. For example, the coating may be characterized by a stress that is less than or more compressive than about −175 MPa, such as less than or about −200 MPa, less than or about −225 MPa, less than or about −250 MPa, or less. A more compressive stress may enable the coating to adhere better to the surfaces defining the processing region, and better coat edges and structured surfaces. In addition, the produced coatings may be characterized by a higher index of refraction than a conventional coating. For example, the coating may have an index of refraction that is greater than or about 1.45, and which may be greater than or about 1.455, greater than or about 1.456, greater than or about 1.457, greater than or about 1.458, greater than or about 1.459, greater than or about 1.460, greater than or about 1.461, greater than or about 1.462, greater than or about 1.463, greater than or about 1.464, greater than or about 1.465, or greater, which may be indicative of a higher structural density of the film.

Subsequent to formation of the coating or seasoning, a substrate, such as the substrate 103, may be placed within the processing region at operation 215. For example, a substrate support, such as the substrate support 104, may be coated with the silicon oxide during the method, and the substrate may be positioned overlying the coating on the substrate support. For example, the substrate may be positioned on the coating formed over the substrate support. Exemplary substrates may include any number of materials, including silicon, silicon germanium, as well as substrates including any number of previously formed films, including oxides, nitrides, or any other materials that may be formed on a semiconductor substrate.

At optional operation 220, a plasma may be formed of various precursors to perform a deposition. It is to be understood that chambers including coatings according to embodiments of the present technology may be used in any number of semiconductor deposition process utilizing a high-powered plasma. The plasma may be formed at an HFRF power of greater than or about 2000 W, and may be formed at a plasma power of greater than or about 2200 W, greater than or about 2400 W, greater than or about 2600 W, greater than or about 2800 W, greater than or about 3000 W, greater than or about 3200 W, or higher. As noted, exemplary processing may form any number of films or materials in chambers incorporating seasoning according to some embodiments of the present technology. As one non-limiting example, an amorphous carbon hardmask may be formed utilizing one or more carbon-containing precursors. For example, the carbon-containing precursor may be or include any alkane, alkene, or any other carbon-containing material. The precursor may include carbon-and-hydrogen-containing precursors, which may include any amount of carbon and hydrogen bonding. In some embodiments the carbon-containing precursor may consist of carbon-to-carbon and carbon-and-hydrogen bonding.

The plasma effluents may deposit on the substrate and form a hardmask film, which may be or include a carbon-containing hardmask film, at optional operation 225. For example, the hardmask film may include amorphous carbon, although it is to be understood that any deposition may be performed to produce a film including any material that does not react with the coating. The hardmask or other film that is formed in the chamber with the coating described above may have incorporated fewer than five defect particles having a diameter greater than 45 nm, fewer than four defect particles having a diameter greater than 45 nm, fewer than three defect particles having a diameter greater than 45 nm, or fewer than two defect particles having a diameter greater than 45 nm, as well as fewer than five defect particles having a diameter greater than 1μm, fewer than four defect particles having a diameter greater than 1 μm, fewer than three defect particles having a diameter greater than 1 μm, or fewer than two defect particles having a diameter greater than 1 μm, for a film thickness greater than or about 1 μm, greater than or about 2 μm, greater than or about 3 μm, greater than or about 4 μm, or higher. In contrast, a hardmask or other film that is formed in the chamber with a conventional coating may have a number of defect particles that increases as a function of the film thickness, and may have incorporated more than 55 defect particles having a diameter greater than 45 nm, more than 60 defect particles having a diameter greater than 45 nm, more than 65 defect particles having a diameter greater than 45 nm, or more than 70 defect particles having a diameter greater than 45 nm, as well as more than 20 defect particles having a diameter greater than 1 μm, more than 25 defect particles having a diameter greater than 1 μm, more than 30 defect particles having a diameter greater than 1 μm, or more than 35 defect particles having a diameter greater than 1 μm, for a film thickness greater than or about 4 μm. Further, the hardmask film that is formed in the chamber with the coating described above may have a substantially constant number of defect particles for a film thickness of greater than or about 1 μm, greater than or about 2 μm, greater than or about 3 μm, greater than or about 4 μm, or higher.

After the deposition process has been completed, such as by forming the bulk film to a desired thickness, the substrate may be removed from the processing region at optional operation 230. In some embodiments a chamber clean may be performed at optional operation 235, which may be similar or identical to the clean performed at operation 205 described previously. For example, performing a chamber clean at optional operation 235, may restart method 200 in some embodiments for an additional substrate. The chamber clean may utilize a halogen-containing precursor, which may be plasma enhanced within the processing region to facilitate removal of residual materials. In some embodiments of the present technology, the clean may be performed at a plasma power of greater than or about 2000 W to facilitate removal of the dense coating formed on the chamber components. Additionally, in some embodiments the plasma power during cleaning may be greater than or about 2200 W, greater than or about 2400 W, greater than or about 2600 W, greater than or about 2800 W, or higher. Because the cleaning may remove the coating previously formed, and may expose underlying chamber components, in some embodiments the cleaning plasma power may be maintained below or about 3000 W, and may be maintained below or about 2800 W, below or about 2600 W, or lower. Accordingly, a plasma power during cleaning may be maintained below or about a plasma power during deposition of the chamber coating. The cleaning process may remove some or all aspects of the residual carbon material, and may remove some or all of the seasoning coating in some embodiments. The coating may be removed and recoated without opening the chamber, which may shorten the down time of the chamber.

The process may then be repeated for a subsequent substrate. In some embodiments the full method may not be repeated. The method may be initiated with any of the noted operations in some embodiments.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursor, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A method comprising:
forming a first plasma of a silicon-containing precursor and an oxygen-containing precursor within a processing region of a semiconductor processing chamber; and
depositing a coating from first effluents of the first plasma on surfaces defining the processing region to a target thickness of greater than or about 0.5 μm, wherein:
forming the first plasma occurs at a first plasma power greater than or about 300 W, and
the surfaces defining the processing region comprise a surface of a faceplate that faces the processing region.

2. The method of claim 1, wherein a flow rate of the silicon-containing precursor is maintained at less than or about 200 sccm.

3. The method of claim 2, wherein the silicon-containing precursor comprises silane.

4. The method of claim 1, wherein the coating comprises silicon oxide.

5. The method of claim 1, wherein the surfaces defining the processing region further comprise a surface of a substrate support.

6. The method of claim 1, wherein a temperature of the processing region is maintained at greater than or about 600° C. during the depositing of the coating.

7. The method of claim 1, wherein the first power is approximately 500 W.

8. The method of claim 1, wherein the first plasma is formed by a high-frequency radio frequency (HFRF) process.

9. The method of claim 1, further comprising, after depositing the coating:
forming a second plasma within the processing region; and
depositing a hardmask film from second effluents of the second plasma on a substrate within the processing region,
wherein forming the second plasma occurs at a second plasma power greater than or about 2500 W.

10. The method of claim 9, wherein the hardmask film comprises amorphous carbon.

11. The method of claim 9, wherein the second power is approximately 2950 W.

12. The method of claim 9, further comprising, after depositing the hardmask film, removing the coating from the surfaces defining the processing region, wherein the removing is performed with a plasma, and wherein the plasma for removing is formed at a power of greater than or about 2000 W.

13. The method of claim 12, wherein the plasma for removing is formed at a power of less than or about 2800 W.

14. A method comprising:
forming a first plasma of a silicon-containing precursor and an oxygen-containing precursor within a processing region of a semiconductor processing chamber;
depositing a coating from first effluents of the first plasma on surfaces defining the processing region, wherein the coating is characterized by a density greater than or about 2.8 g/cm³,
subsequently forming a second plasma within the processing region; and
depositing a hardmask film from second effluents of the second plasma on a substrate within the processing region, wherein:
forming the first plasma occurs at a first power greater than or about 300 W, and
forming the second plasma occurs at a second power greater than or about 2500 W.

15. The method of claim 14, wherein the coating is formed to have a refractive index greater than 1.46.

16. The method of claim 14, further comprising:
forming a plasma of a halogen-containing precursor, and
removing the coating from surfaces defining the processing region.

17. The method of claim 16, wherein the plasma of the halogen-containing precursor is formed at a plasma power of greater than or about 2000 W.

18. A method comprising:
forming a first plasma of a silicon-containing precursor and an oxygen-containing precursor within a processing region of a semiconductor processing chamber;
depositing a coating from first effluents of the first plasma on surfaces defining the processing region, wherein the coating is characterized by an internal stress of less than −175 MPa;
subsequently forming a second plasma within the processing region; and
depositing a hardmask film from second effluents of the second plasma on a substrate within the processing region, wherein:
forming the first plasma occurs at a first power greater than or about 300 W, and
forming the second plasma occurs at a second power greater than or about 2500 W.

19. The method of claim 18, further comprising:
forming a plasma of a halogen-containing precursor, and
removing the coating from surfaces defining the processing region.

20. The method of claim 19, wherein the plasma of the halogen-containing precursor is formed at a plasma power of greater than or about 2000 W.
